(19) United States
(12) Patent Application Publication
(10) Pub. No.: US 2018/0332717 A1
(43) Pub. Date: Nov. 15, 2018

(54) METHOD FOR FULL FILLING INTER-LAYER BLIND HOLE OF HDI RIGID-FLEX LAMINATE WITH COPPER

(71) Applicant: AKM Electronics Technology (Suzhou) Co., Ltd., Suzhou City (CN)

(72) Inventor: Jiangtao ZHOU, Suzhou City (CN)

(73) Assignee: AKM Electronics Technology (Suzhou) Co., Ltd., Suzhou City (CN)

(21) Appl. No.: 15/772,440

(22) PCT Filed: Nov. 16, 2015
(86) PCT No.: PCT/CN2015/094736

§ 371 Date: Apr. 30, 2018

(30) Foreign Application Priority Data
Oct. 28, 2015 (CN) 201510713485.3

(51) Int. Cl. H05K 3/36; H05K 3/42; H05K 1/11; H05K 3/46; H05K 1/02

(52) U.S. Cl. CPC H05K 3/361; H05K 3/421; H05K 2203/14; H05K 3/4623; H05K 1/0298; H05K 1/115

(57) ABSTRACT

A method for copper filling-up of blind vias in HDI rigid-flex PCB is provided which includes the steps of: 1) performing a copper reduction on a single side of a double sided copper-clad laminate; 2) drilling blind vias with inverted trapezoidal shape in a side of the double sided copper-clad laminate being copper reduced by laser; 3) cleaning via walls and the via bottoms of the blind vias to remove the residues left during the drilling process; 4) depositing metallic copper layers on surfaces of the via walls and the via bottoms of the blind vias; 5) filling the blind vias with copper after the blind vias being deposited by metallic copper layer. The copper filling-up of the blind vias in the HDI rigid-flex PCB is achieved, leading to decreased cost of equipment investment and improved production efficiency and benefits.

PRIORITY

This application is a National Phase Entry of PCT International Application No. PCT/CN2015/094736, which was filed on Nov. 16, 2015, and claims priority to Chinese Patent Application No. 201510713485.3, which was filed on Oct. 28, 2015, the contents of each of which are incorporated herein by reference.

### FIELD OF TECHNOLOGY

The following belongs to the field of HDI rigid-flex PCB, and it particularly refers to a method for copper filling-up of blind vias in HDI rigid-flex PCB.

### BACKGROUND

With the higher level of integration of electron device, especially with the increasing development of wearable device, higher requirement are necessary for the HDI (high density interconnect) rigid-flex PCB (printed circuit board). The HDI rigid-flex PCB refers to a printed circuit board with one or more rigid region and one or more flex region which are optionally interconnected. Blind vias are necessary in the HDI rigid-flex PCB for an optional interconnection between layers of the HDI rigid-flex PCB, thus the preparation and filling of the blind vias in HDI rigid-flex PCB are vital. Recently, the filling of the blind vias in HDI rigid-flex PCB is performed by drilling through CO₂ laser, copper deposition, copper plating and then resin filling. The existing blind via filling method easily causes drawbacks of thin copper in the blind via, which will lead to many problems, for example, the copper in the blind via will easily break leading to bad conductivity, other bonding pads are needed due to poor weldability which will decrease the wiring density on HDI board, the process of resin filling is needed which will increase equipment investment, and so on.

In the ordinary printed circuit board, an all-copper filling method of blind via is widely used, and it has following benefits:
1) Penetrating through the bonding pad or absence of bonding pad can be achieved, which significantly increase the wiring density;
2) Theoretically, any layers can be interconnected through the technology of stacked blind vias in layers;
3) Flexible micro-metal bones can be obtained to significantly enhance the mechanical strength of the HDI rigid-flex PCB;
4) The thermal conductivity can be highly enhanced and the performance of heat dissipation between layers is improved.
   The process of resin filling can be omitted, which shortens the production cycle and decreases the equipment investment.

However, it has never been reported the copper filling-up of blind vias in HID rigid-flex PCB yet, because the blind vias in the HID rigid-flex PCB are distributed in rigid region, flexible region, and rigid-flex region, and the varying difficulty level of copper filling-up in different regions varies, especially in the rigid-flex regions. In the rigid-flex region, the blind vias are formed by different materials, normally including FR4, PI, adhesive glue, etc. The blind vias are usually drilled through laser, and the copper, FR4, PI, and adhesive glue are different in their hot-melt property when being treated with the laser, this makes the structure of formed vias complicated and the roughness of via walls vary greatly. Besides, the rigid region has thicker substrate, but the flexible region has thinner substrate, resulting in broad distribution of thickness-diameter ratio. In the blind via with bigger thickness-diameter ratio, the agent for filling the blind vias is difficult to reach the via bottom, and phenomena such as via sealing and via capping are likely to occur during the filling process. The blind via with smaller thickness-diameter ratio is hard to be filled from bottom to top due to the small difference in the via between the inner and external of the vias. The above complicated features of the blind vias in the rigid-flex region largely increase the difficulties of cooper filling in the rigid-flex PCB, and hinder a further improvement of the HDI rigid-flex PCB.

Now it is urgently required a process for filling blind vias in HDI rigid-flex PCB, which is capable of overcoming the drawbacks in the prior art and solving the above problems.

### SUMMARY

It is an objective of the present invention to provide a method for copper filling-up of blind via in HDI rigid-flex PCB. It can achieve the all-copper filling of the bind via, making sure the conductivity between layers of the blind vias, increasing the wiring density on HDI rigid-flex PCB and lowering the cost of equipment investment.

In order to achieve the above objective, the present invention applies following technical solution.

A method for copper filling-up of blind vias in HDI rigid-flex PCB comprises:

1) performing a copper reduction on a single side of a double sided copper-clad laminate;

2) drilling blind vias with inverted trapezoidal shape in the side of the double sided copper-clad laminate being copper reduced by laser;

3) cleaning the via wall and the via bottom to remove the residues left during the drilling process;

4) depositing metallic copper layers on the surfaces of the via wall and the via bottom of the blind via;

5) filling the blind vias with copper after the blind vias being deposited by metallic copper layer, to achieve an interconnection between layers of the HDI rigid-flex PCB.

Preferably, in step 1), a dry film is coated on one side of the double sided copper-clad laminate, and the copper reduction on a single side is performed on the other side uncoated with the dry film.

Preferably, in step 2), an UV laser is used for drilling.

Preferably, in step 2), in the blind via, the upper via diameter A is larger than the lower via diameter B, and B 0.6A.

Preferably, in step 3), a wet adhesive-removing process is applied to clean the via wall and the via bottom of the bind via.

Preferably, in step 3), the via wall and via bottom of the blind via after cleaning have a roughness Ra of 500-1000 nm.

Preferably, in step 4), an electroless copper process is applied for depositing metallic copper layers on the surfaces of the via wall and the via bottom of the blind via. The metallic copper layer has a thickness of 0.2-1 μm.

Preferably, in step 5), an electroplating process for blind via filling is applied to fully fill the blind vias with copper. It is specifically performed by an electroplating with a current density of 10-16 ASF in 40-80 minutes, and all-copper filling on the filling agent line.

In the electroplating process, the electroplating agent comprises 220±20 g/L CuSO₄.5H₂O, 50±10 g/L H₂SO₄, 50±10 ppm chloride ion, 1.0±0.2 mL/L accelerator, 1.0±0.2 mL/L inhibitor and 1.0±0.2 mL/L leveler.

By applying the above technical solution, the present invention has following benefits.

In the method for copper filling-up of blind vias in HDI rigid-flex PCB, the blind vias are fully filled with copper, which guarantees the conductivity between layers of the rigid-flex PCB, increases the wiring density on HDI rigid-flex PCB, thus lead to a smaller volume. Besides, the thermal conductivity is highly enhanced and the performance of heat dissipation between layers is improved.

In the method for copper filling-up of blind vias in HDI rigid-flex PCB of the present invention, a copper reduction on a single surface is performed on one side of the double sided copper-clad laminate, blind vias are drilled thereon by laser before subsequent adhesive removing and copper deposition, and eventually an electroplating process for blind via is applied to fill the blind via with copper, whereby an interconnection between layers of the rigid-flex PCB is achieved. In the method of all-copper filling of blind via in HDI rigid-flex PCB of the present invention, the process of resin filling after the electroplating of blind via can be omitted, which saves the cost and time and improves the production efficiency and benefits.

### BRIEF DESCRIPTION OF THE DRAWINGS

FIG. 1 is a schematic diagram showing the drilled blind via in the HDI rigid-flex PCB of the present invention;

FIG. 2 is a structural diagram of the cross section of the HDI rigid-flex PCB prepared through the method of the present invention; wherein,

1 interior layer of circuit;

2 outer layer of blind vias;

3 interior layer of PI;

4 outer layer of copper plating;

5 FR-4 (epoxy glass fabric laminated board).

### DETAILED DESCRIPTION OF PREFERRED EMBODIMENTS

The present invention will be further explained with reference to figures and embodiments.

In the following embodiments, the double sided copper-clad laminate is commercially available, the accelerator 3620A, inhibitor 3620S and leveler 3620L are produced by Shanghai SINYANG Semiconductor Materials Co., Ltd.

### Embodiment 1

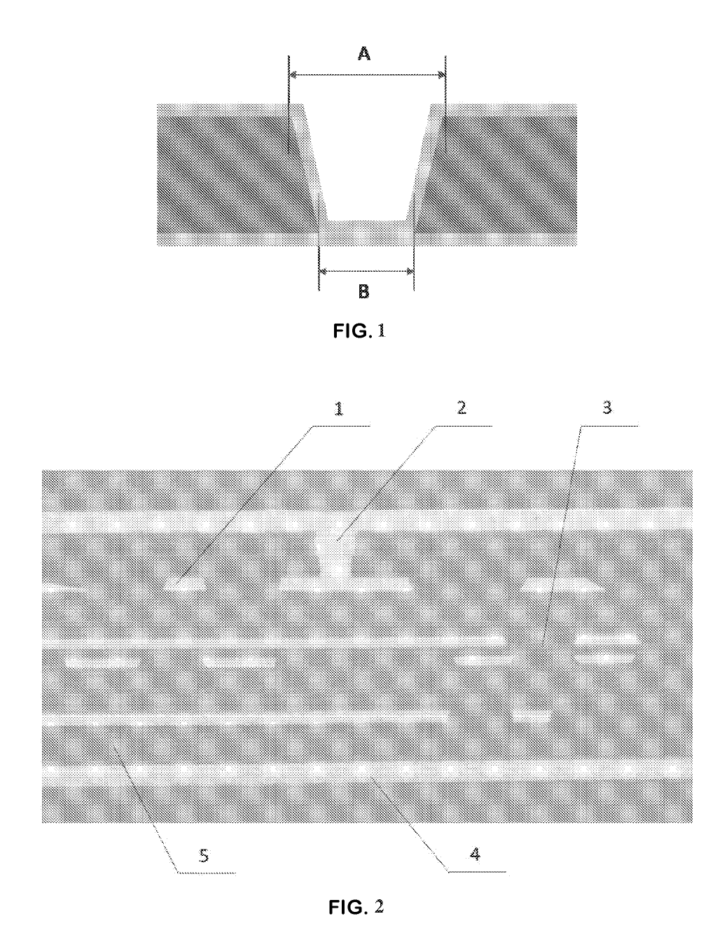

As shown in FIGS. 1 and 2, a method for copper filling-up of blind vias in HDI rigid-flex PCB is performed as following.

1) A double sided copper-clad laminate is prepared, wherein copper coils having 18 μm thickness on its upper and lower sides are comprised, and a substrate having thickness of 75 μm is sandwiched therebetween. A dry film is coated on one side of the double sided copper-clad laminate, and a copper reduction on a single surface is applied to the other side without the dry film through horizontal copper reduction line, whereby the thickness of the copper coil after copper reduction is 7 μm.

2) Drilling data for the blind vias in HDI rigid-flex PCB are prepared through CAD software, and the vias are drilled in the side of the double sided copper-clad laminate being copper reduced, by applying UV laser drilling according to the drilling data; the formed blind via is inverted trapezoidal shaped, wherein A is the upper via diameter of the blind via, B is the lower via diameter of the blind via, and A>B≥0.6*A, as show in FIG. 1.

3) The via wall and the via bottom of blind via in the HDI rigid-flex PCB are cleaned by wet adhesive-removing process, to remove the residual adhesive left during the drilling process; a certain roughness Ra between 500-1000 nm is formed in the via wall and the via bottom, for subsequent convenient chemical copper covering and deposition.

4) The via wall and the via bottom of blind via in the HDI rigid-flex PCB are metallized by an electroless copper plating process including 30-second activation, 10-second microetching and 50-minute copper deposition, and therefore chemical copper layer of 0.2-1 μm thickness is deposited on the via wall and via bottom of the blind via.

5) An electroplating process for blind via filling is applied to fill the blind vias with copper after the blind vias being deposited by chemical copper, to achieve an interconnection between layers of the HDI rigid-flex PCB, wherein the electroplating process is specifically performed with a current density of 10-16 ASF in 40-80 minutes, and copper filling-up on the filling agent line; in this embodiment, the electroplating agent applied in the electroplating process comprises 200 g/L CuSO₄.5H₂O, 40 0gL H₂SO₄, 40 ppm chloride ion, 0.8 mL/L accelerator, 12 mL/L inhibitor and 12 mL/L leveler. The blind vias are filled up after the electroplating, and the circuit is flat.

### Embodiment 2

This embodiment is basically the same as the embodiment 1, and they differ in that in step 5), the electroplating agent applied in the electroplating process comprises 220 g/L CuSO₄.5H₂O, 50 g/L H₂SO₄, 50 ppm chloride ion, 1.0 mL/L accelerator, 15 mL/L inhibitor and 15 mL/L leveler. The blind vias are filled up after the electroplating, and the circuit is flat.

### Embodiment 3

This embodiment is basically the same as the embodiment 1, and they differ in that in step 5), the electroplating agent applied in the electroplating process comprises 240 g/L CuSO₄.5H₂0, 60 g/L H₂SO₄, 60 ppm chloride ion, 1.2 mL/L accelerator, 18 mL/L inhibitor and 18 mL/L leveler. The blind vias are filled up after the electroplating, and the circuit is flat.

In the method for copper filling-up of blind vias in HDI rigid-flex PCB of the above embodiments, a copper reduction on a single surface is performed on one side of the double sided copper-clad laminate, blind vias are drilled thereon by laser before subsequent adhesive removing and copper deposition, and eventually an electroplating process for blind vias is applied to fill the blind vias with copper, whereby an interconnection between layers of the rigid-flex PCB is achieved, which saves the cost and time and improves the production efficiency and benefits.

The embodiment described hereinbefore is merely preferred embodiment of the present invention and not for purposes of any restrictions or limitations on the invention. It will be apparent that any non-substantive, obvious alterations or improvement by the technician of this technical field according to the present invention may be incorporated into ambit of claims of the present invention.

1. A method for copper filling-up of blind vias in HDI rigid-flex PCB, comprising the steps of:
1) performing a copper reduction on a single side of a double sided copper-clad laminate;
2) drilling blind vias with inverted trapezoidal shape in a side of the double sided copper-clad laminate being copper reduced by laser;
3) cleaning via walls and the via bottoms of the blind vias to remove the residues left during the drilling process;
4) depositing metallic copper layers on surfaces of the via walls and the via bottoms of the blind vias; and
5) filling the blind vias with copper after the blind vias being deposited by metallic copper layer, to achieve an interconnection between layers of the HDI rigid-flex PCB.

2. The method for copper filling-up of blind vias in HDI rigid-flex PCB according to claim 1, wherein in step 1), a dry film is coated on one side of the double sided copper-clad laminate, and the copper reduction on a single surface is performed on the other side without the dry film.

3. The method for copper filling-up of blind vias in HDI rigid-flex PCB according to claim 1, wherein in step 2), an UV laser is used for drilling.

4. The method for copper filling-up of blind vias in HDI rigid-flex PCB according to claim 1, wherein in step 2), in the blind vias, an upper via diameter A is larger than a lower via diameter B, and B

5. The method for copper filling-up of blind vias in HDI rigid-flex PCB according to claim 1, wherein in step 3), a wet adhesive-removing process is applied to clean the via walls and the via bottoms of the blind vias.

6. The method for copper filling-up of blind vias in HDI rigid-flex PCB according to claim 1, wherein in step 3), the via walls and via bottoms of the blind vias after cleaning have a roughness Ra of 500-1000 nm.

7. The method for copper filling-up of blind vias in HDI rigid-flex PCB according to claim 1, wherein in step 4), an electroless copper plating process is applied for depositing the metallic copper layers on surfaces of the via walls and the via bottoms of the blind vias.

8. The method for copper filling-up of blind vias in HDI rigid-flex PCB according to claim 1, wherein the metallic copper layer has a thickness of 0.2-1 μm.

9. The method for copper filling-up of blind vias in HDI rigid-flex PCB according to claim 1, wherein in step 5), an electroplating process for blind via filling is applied to fill the blind vias with copper, and it is specifically performed by an electroplating with a current density of 10-16 ASF in 40-80 minutes, and copper filling-up on the filling agent line.

10. The method for copper filling-up of blind vias in HDI rigid-flex PCB according to claim 9, wherein in the electroplating process, an electroplating agent comprises 220±20 g/L CuSO₄5H₂O, 50±10 g/L H₂SO₄, 50±10 ppm chloride ion, 1.0±0.2 mL/L accelerator, 1.0±0.2 mL/L inhibitor and 1.0±0.2 mL/L leveler.

11. The method for copper filling-up of blind vias in HDI rigid-flex PCB according to claim 3, wherein in step 2), in the blind vias, an upper via diameter A is larger than a lower via diameter B, and B 0.6A.

12. The method for copper filling-up of blind vias in HDI rigid-flex PCB according to claim 5, wherein in step 3), the via walls and via bottoms of the blind vias after cleaning have a roughness Ra of 500-1000 nm.

13. The method for copper filling-up of blind vias in HDI rigid-flex PCB according to claim 7, wherein the metallic copper layer has a thickness of 0.2-1 μm.
